(19) United States
(12) Patent Application Publication
(10) Pub. No.: US 2025/0388458 A1
(43) Pub. Date: Dec. 25, 2025

(54) MEMS MICROPHONE

(71) Applicant: AAC Technologies Pte. Ltd., Singapore (SG)

(72) Inventor: Euan James Boyd, EB (GB)

(21) Appl. No.: 18/748,093

(22) Filed: Jun. 20, 2024

(51) Int. Cl. B81B 3/00; H04R 7/06

(52) U.S. Cl. CPC B81B 3/0072; H04R 7/06; B81B 2201/0257; B81B 2203/0127; B81B 2203/0307; B81B 2203/0315

(57) ABSTRACT

A MEMS microphone includes a substrate, a back plate and a diaphragm. The diaphragm includes a membrane body, an edge portion fixedly connected to the substrate, a plurality of isolation islands spaced apart from the membrane body forming a slit between the membrane body and each of the plurality of the isolation islands, and a plurality of beams located between two adjacent isolation islands and disposed at intervals along a circumferential direction of the diaphragm. The MEMS microphone further includes a connecting piece configured to fixedly connect each of the plurality of isolation islands with at least to one of the substrate and the back plate. Each isolation island is fixedly connected to the back plate and/or the substrate, which can optimize the degree of freedom of the isolation island design and improve the firmness of the diaphragm.

### TECHNICAL FIELD

The present disclosure relates to the technical field of microphones, and in particular to a MEMS microphone.

### BACKGROUND

Currently, micro-electro-mechanical-system microphone (abbreviated as MEMS microphone) is widely popular and has relatively better performance, which is also called silicon-based microphone or silicon microphone as it is made of silicon-based semiconductor materials. Its packaging volume is smaller than the conventional electret microphone, and it is becoming more and more widely used.

The silicon microphone in the related technologies is generally etched at an edge of the diaphragm along the circumferential direction of the diaphragm to form plural connecting beams spaced apart from each other. The beams are formed by a plurality of flaps which mechanically isolated the beams from the rest of the diaphragm. The connecting beams are fixedly connected to the substrate, so as to achieve the connection between the central portion of the diaphragm and the substrate. This design method can reduce the rigidity of the diaphragm. However, since the diaphragm is made of flexible material, the flaps used to isolate the beams are likely to warp due to stress gradient and/or suffer from stiction to the substrate or fixed back plate structure.

Therefore, it is desirable to provide a new MEMS microphone to solve the above technical problems.

### SUMMARY

Embodiments of the present disclosure are intended to provide a MEMS microphone which can avoid warping of the isolation island.

To achieve the above object, embodiments of the present disclosure provide a MEMS microphone including comprising: a substrate with a back cavity, a back plate spaced apart from substrate, a diaphragm arranged between the substrate and the back plate and supported on the substrate, including: a membrane body spaced apart from the substrate and the back plate; an edge portion fixedly connected to the substrate; a plurality of isolation islands spaced apart from the membrane body, formed by a slit in the membrane body and each of the plurality of the isolation islands; and a plurality of beams located between two adjacent isolation islands and disposed at intervals along a circumferential direction of the diaphragm, connecting the edge portion with the membrane body, a connecting piece configured to fixedly connect each of the plurality of isolation islands with at least to one of the substrate and the back plate.

As an improvement, the connecting piece is fixedly connected to the back plate, and the connecting piece is integrally formed with the back plate.

As an improvement, the connecting piece includes a first connecting portion and a second connecting portion fixedly connected with the first connecting portion, the first connecting portion is fixedly connected to the back plate, and the second connecting portion is fixedly connected with a corresponding one of the plurality of isolation islands.

As an improvement, a cross-sectional area of the first connecting portion is larger than that of the second connecting portion.

As an improvement, a cross-section of the first connecting portion and a cross-section of the second connecting portion are both circular.

As an improvement, an air gap is formed between each of the plurality of isolation islands and the back plate.

As an improvement, a connecting surface is formed at a position where the first connecting portion is fixedly connected with the second connecting portion; and along a vibration direction of the diaphragm, the air gap includes a first gap formed between a surface, facing towards the corresponding one of the plurality of isolation islands, of the back plate and the connecting surface, and includes a second gap formed between a surface, facing towards the back plate, of the corresponding one of the plurality of isolation islands and the connecting surface.

As an improvement, the connecting piece is fixedly connected to the substrate; and the connecting piece is integrally formed with the substrate.

As an improvement, the connecting piece includes an anchor which is fixedly connected between the corresponding one of the plurality of isolation islands and the substrate.

As an improvement, a cross-section of the anchor along a direction perpendicular to a vibration direction of the diaphragm is a hollow rounded rectangle; and the anchor is filled with an oxide isolation layer.

As an improvement, along a vibration direction of the diaphragm, an orthographic projection of each of the plurality of isolation islands on the back plate covers that of the connecting piece on the back plate; and/or, an orthographic projection of each of the plurality of isolation islands on the substrate covers that of the connecting piece on the substrate.

As an improvement, along a vibration direction of the diaphragm, an orthographic projection of the connecting piece on the corresponding one of the plurality of isolation islands is located in the center of the corresponding one of the plurality of isolation islands.

As an improvement, the beam is located between two adjacent slits.

The present disclosure has the following beneficial effects: in the MEMS microphone according to the present disclosure, the isolation island is fixedly connected with at least one of the back plate and the substrate through a connecting piece, so that the isolation island can be fixed to prevent warpage of the isolation island due to stress gradient and/or stiction to the substrate or fixed back plate structure. On the one hand, the size design of the isolation island would be subjected to less limitations due to the fixed position of the isolation island, optimizing the degree of freedom of the isolation island design; and on the other hand, also due to the fixed position of the isolation island, the isolation island structure provides a certain degree of ventilation when the diaphragm moves upward under high pressure, improving the firmness of the diaphragm.

### BRIEF DESCRIPTION OF THE DRAWINGS

Fig.1 is a structural diagram of a MEMS microphone according to a first embodiment of the present disclosure.

Fig.2 is a structural diagram of a diaphragm and a substrate of the MEMS microphone according to the first embodiment of the present disclosure.

Fig.3 is a cross-sectional view of the MEMS microphone at an island, according to the first embodiment of the present disclosure.

Fig.4 is a structural diagram of the MEMS microphone in Fig.1.

Fig.5 is a bottom view of the isolation island and the connecting piece of the MEMS microphone in Fig.1.

Fig.6 is a structural diagram of a MEMS microphone according to a second embodiment of the present disclosure.

Fig.7 is a top view of an isolation island and a connecting piece of the MEMS microphone according to the second embodiment of the present disclosure.

Fig.8 is a structural diagram of a MEMS microphone according to a third embodiment of the present disclosure.

### DETAILED DESCRIPTION OF THE EMBODIMENTS

The present disclosure will be further described below in combination with the accompanying drawings and embodiments.

It should be noted that all directional indications (such as up, down, left, right, front, back, inside, outside, top, bottom, etc.) in the embodiments of the present disclosure are only used to explain the relative position relationship between components under a specific attitude (as shown in the accompanying drawings). If the specific attitude changes, these directional indications will also change accordingly.

It should further be noted that when an element is described as being "fixed" or "disposed" on another element, the former element may be directly on another element or there may be an intermediate element therebetween at the same time. When an element is described as "connecting" with another element, it may be directly connected with another element or there may be an intermediate element therebetween at the same time.

### First Embodiment

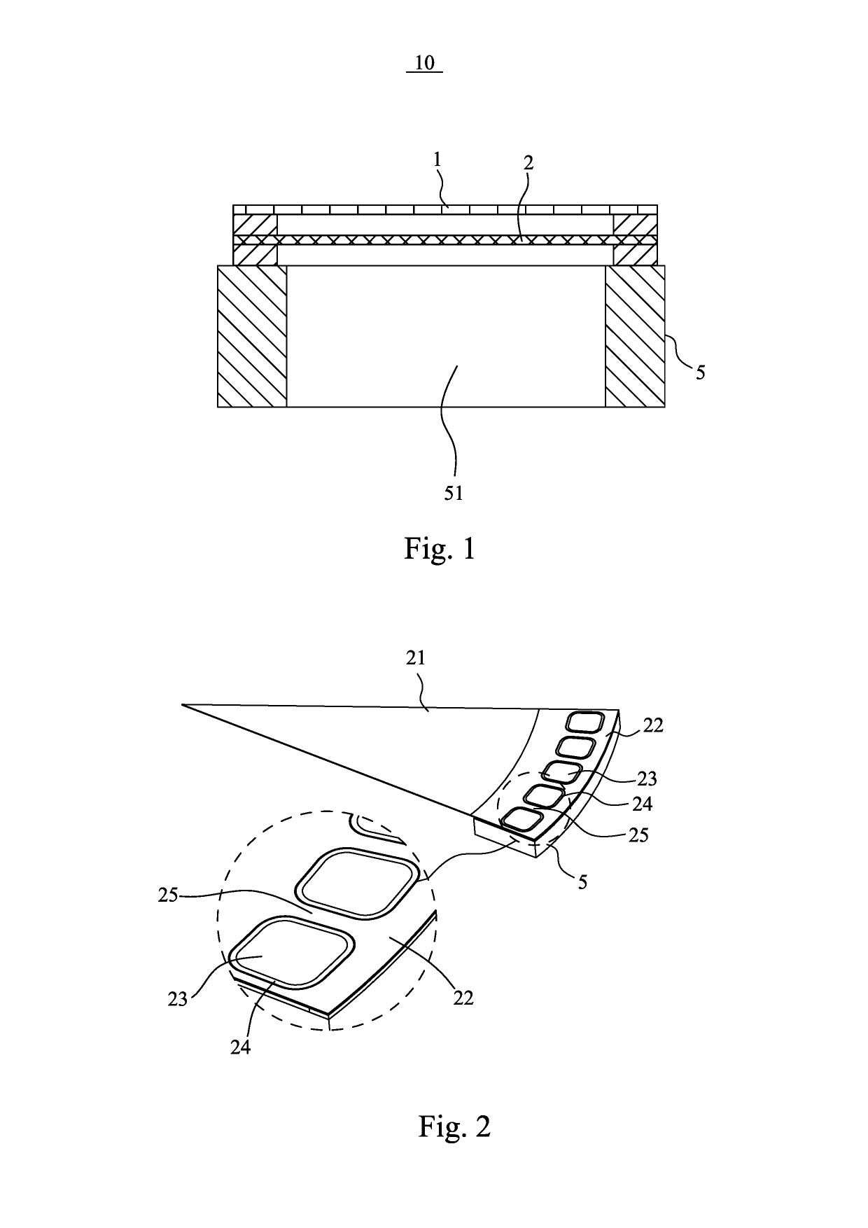

Referring to FIG. 1 and FIG. 2, the first embodiment of the present disclosure provides a MEMS microphone 10 including a substrate 5 with a back cavity 51, a back plate 1 spaced apart from the substrate 5, and a diaphragm 2 arranged between the substrate 5 and the back plate 3 and supported on the substrate 5. Specifically, the diaphragm 2 includes a membrane body 21 spaced apart from the substrate 5 and the back plate 3, an edge portion 22 fixedly connected to the substrate 5 through a fixation portion 6, a plurality of isolation islands 23 spaced apart from the membrane body 21 forming a slit 24 between the membrane body 21 and each of the plurality of the isolation islands 23, and a plurality of beams 25 located between two adjacent isolation islands 23 and disposed at intervals along a circumferential direction of the diaphragm 2. One end of the beam 25 is connected to the edge portion 22, the other end of the beam 25 is connected to the membrane body 21. Furthermore, the MEMS microphone 10 includes a connecting piece 3 configured to fixedly connect each of the plurality of isolation islands 23 with the substrate 5.

Specifically, the slit 24 is annular surrounding the isolation island 23. Thus, the isolation island 23 is spaced apart from the membrane body 21 and the beam 25 simultaneously. Furthermore, the isolation island 23 and the membrane body 21 are located on a same plane. It should be noted that the beam 25 is located between two adjacent slits 24.

With reference to FIG. 1 and FIG. 2, the isolation island 23 is in a rounded rectangle shape. Correspondingly, the slit 213 is in a hollow rounded rectangle shape. In other embodiments, the isolation island 23 may also be circular or polygonal, which can be designed according to actual needs and is not limited here.

In the MEMS microphone 10 according to the first embodiment of the present disclosure, each isolation island 23 is fixedly connected with the substrate 5 through the connecting piece 3, so that the isolation island 23 can be fixed to prevent warpage of the isolation island 23 due to stress gradient and/or stiction to the substrate 5 or fixed back plate structure. On the one hand, the size design of the isolation island 23 would be subjected to fewer limitations due to the fixed position of the isolation island 23, optimizing the degree of freedom of the isolation island 23 design. On the other hand, also due to the fixed position of the isolation island 23, the isolation island 23 structure provides a certain degree of ventilation when the diaphragm 2 moves upward under high pressure, improving the robustness of the diaphragm 2 against high air pressures.

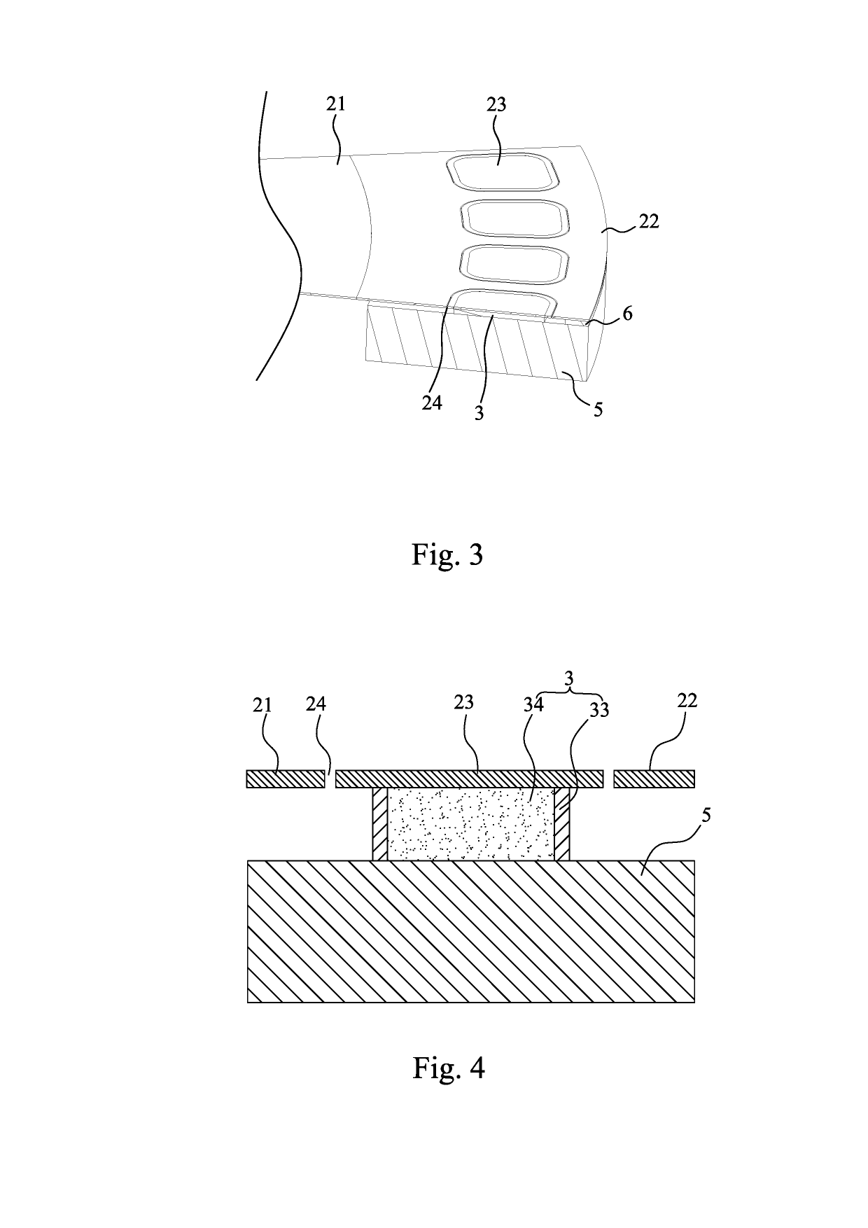

Referring to FIG. 3, the connecting piece 3 includes an anchor 33 which is fixedly connected between the corresponding one of the plurality of isolation islands 23 and the substrate 5, so as to achieve the fixed connection of the connecting piece 3 with the corresponding isolation island 23 and the back plate 1.

Referring to FIG. 4, a cross-section of the anchor 33 along a direction perpendicular to the vibration direction of the diaphragm 2 is a hollow rounded rectangle. In other embodiments, the cross-section of the anchor may also be a circular ring or a polygonal ring, which can be designed according to actual needs and is not limited here.

Referring to FIG. 3 and FIG. 4, the anchor 33 is filled with an oxide isolation layer 34. In other embodiments, the anchor 33 is filled with other materials, which can be designed according to actual needs and is not limited here.

In other embodiments, the connecting piece 3 may include only an oxide isolation layer which is fixedly connected between the corresponding isolation island 23 and the substrate 5 to connect the corresponding isolation island 23 with the substrate 5.

Referring to FIG. 3 and FIG. 4, along the vibration direction of the diaphragm 2, the orthographic projection of the corresponding isolation island 23 on the substrate 5 covers the orthographic projection of the connecting piece 3 on the substrate 5, so that the connecting piece 3 is connected only with the corresponding isolation island 23 of the diaphragm 2, avoiding interference with other positions of the diaphragm 2 (such as the vibration portion or the beam 25).

In this embodiment, each isolation island 23 is fixedly connected with the substrate 5 through the connecting piece 3, so that the isolation island 23 can be fixed to prevent warpage of the isolation island 23 due to stress gradient and/or stiction to the substrate 5 or fixed back plate structure. On the one hand, the size design of the isolation island 23 would be subjected to fewer limitations due to the fixed position of the isolation island 23, optimizing the degree of freedom of the isolation island 23 design. On the other hand, also due to the fixed position of the isolation island 23, the isolation island 23 structure provides a certain degree of ventilation when the diaphragm 2 moves upward under high pressure, improving the firmness of the diaphragm 2.

### Second Embodiment

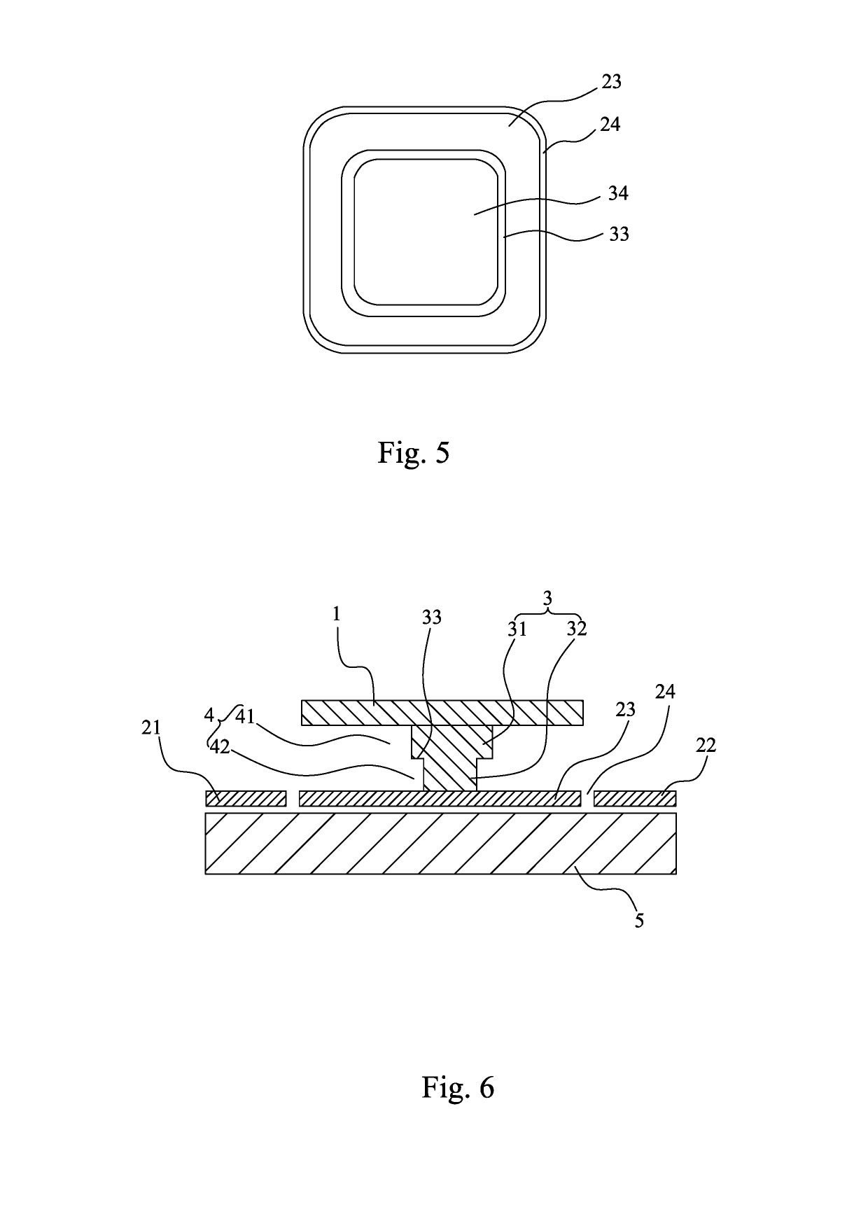

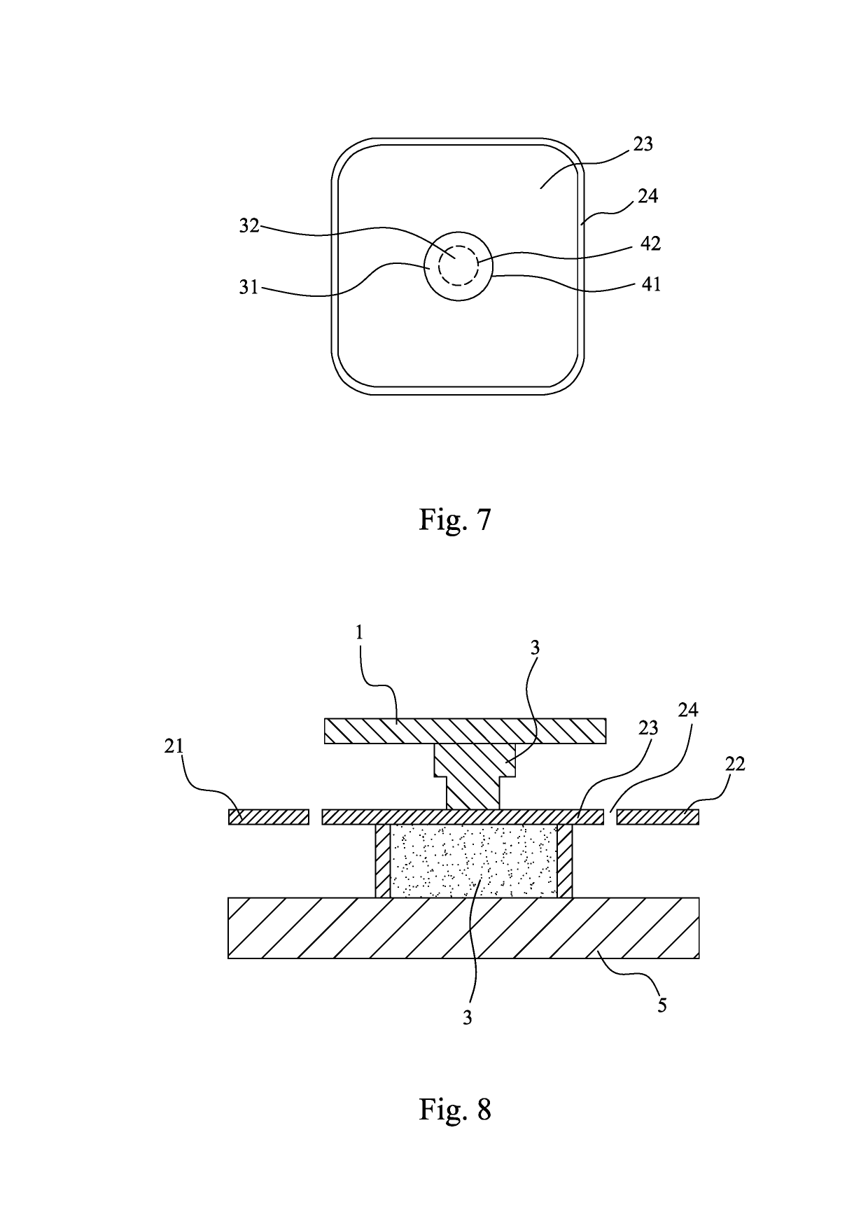

Referring to FIG. 5 and FIG. 6, the difference between the first embodiment and this second embodiment is that the connecting piece 3 configured to fixedly connect each of the plurality of isolation islands 23 with the back plate 1, so as to fix the isolation island 23.

Referring to FIG. 5, the connecting piece 3 includes a first connecting portion 31 and a second connecting portion 32 fixedly connected with the first connecting portion 31. The first connecting portion 31 is fixedly connected to the back plate 1, and the second connecting portion 32 is fixedly connected with a corresponding one of the plurality of isolation islands 23, so as to fixedly connect the connecting piece 3 between the corresponding isolation island 23 and the back plate 1.

Referring to FIG. 5, along a direction perpendicular to a vibration direction of the diaphragm 2, a cross-sectional area of the first connecting portion 31 is larger than that of the second connecting portion 32. As shown in Fig.6, a cross-section of the first connecting portion 31 and a cross-section of the second connecting portion 32 are both circular. In other embodiments of the present disclosure, the cross-section of the first connecting portion 31 and the cross-section of the second connecting portion 32 may also be rectangular, trapezoidal or other shaped, and the cross-sectional area of the first connecting portion 31 may also be smaller than or equal to the cross-sectional area of the second connecting portion 32, which can be designed according to actual needs and is not limited here.

Referring to FIG. 5, along the vibration direction of the diaphragm 2, an air gap 4 is formed between each of the plurality of isolation islands 23 and the back plate 1. A connecting surface 33 is formed at a position where the first connecting portion 31 is fixedly connected with the second connecting portion 32.

Along the vibration direction of the diaphragm 2, the air gap 4 includes a first gap 41 and a second gap 42. The first gap 41 is formed between a surface, facing towards the corresponding one of the plurality of isolation islands 23, of the back plate 1 and the connecting surface 33. The second gap 42 is formed between a surface, facing towards the back plate 1, of the corresponding one of the plurality of isolation islands 23 and the connecting surface 33.

Referring to FIG. 5, along the vibration direction of the diaphragm 2, the orthographic projection of the corresponding isolation island 23 on the back plate 1 covers the orthographic projection of the connecting piece 3 on the back plate 1, so that the connecting piece 3 is connected only with the corresponding isolation island 23 of the diaphragm 2, avoiding interference with other positions of the diaphragm 2 (such as the vibration portion or the beam 25).

Refer to FIG. 5 and FIG. 6, along the vibration direction of the diaphragm 2, the orthographic projection of the connecting piece 3 on the corresponding one of the plurality of isolation islands 23 is located in the center of the corresponding one of the plurality of isolation islands 23, so as to connect the back plate 1 from the center of the isolation island 23.

The connecting piece 3 is integrally formed with the back plate 1. The connecting piece 3 may be formed on the corresponding one of the plurality of isolation islands 23 by deposition. In this case, the connecting piece 3 and the back plate 1 may be made of the same material. The connecting piece 3 may be first deposited on the corresponding isolation island 23, and the back plate 1 then be deposited on the connecting piece 3, so that the connecting piece 3 and the back plate 1 are formed into one piece.

In this embodiment, each isolation island 23 is fixedly connected with the back plate 1 through the connecting piece 3, so that the isolation island 23 can be fixed to prevent warpage of the isolation island 23 due to stress gradient and/or stiction to the substrate 5 or fixed back plate 1 structure. On the one hand, the size design of the isolation island 23 would be subjected to fewer limitations due to the fixed position of the isolation island 23, optimizing the degree of freedom of the isolation island 23 design. On the other hand, also due to the fixed position of the isolation island 23, the isolation island 23 structure provides a certain degree of ventilation when the diaphragm 2 moves upward under high pressure, improving the firmness of the diaphragm 2.

### Third Embodiment

Referring to FIG. 8, the difference between this third embodiment and the above two embodiments is that the isolation islands 23 are configured to fixedly connect to the back plate 1 and the substrate through the connecting piece simultaneously, thus further improving the firmness of the isolation islands 23, and reducing the span of the back plate 1, hence increasing the stiffness of the back plate 1 while maintaining the span of the diaphragm 2 and keeping the stiffness of the diaphragm 2 low.

The above description only shows embodiments of the present disclosure. It should be noted herein that for those skilled in the art, improvements may be made without departing from the inventive concept of the present disclosure, and those improvements still fall within the scope of protection of the present disclosure.

1. A MEMS microphone, comprising:
a substrate with a back cavity,
a back plate spaced apart from substrate;
a diaphragm arranged between the substrate and the back plate and supported on the substrate, including:
a membrane body spaced apart from the substrate and the back plate;
an edge portion fixedly connected to the substrate;
a plurality of isolation islands spaced apart from the membrane body forming a slit between the membrane body and each of the plurality of the isolation islands; and
a plurality of beams located between two adjacent isolation islands and disposed at intervals along a circumferential direction of the diaphragm, connecting the edge portion with the membrane body,
a connecting piece configured to fixedly connect each of the plurality of isolation islands with at least to one of the substrate and the back plate.

2. The MEMS microphone according to claim 1, wherein the connecting piece is fixedly connected to the back plate, the connecting piece is integrally formed with the back plate.

3. The MEMS microphone according to claim 2, wherein the connecting piece includes a first connecting portion and a second connecting portion fixedly connected with the first connecting portion, the first connecting portion is fixedly connected to the back plate, and the second connecting portion is fixedly connected with a corresponding one of the plurality of isolation islands.

4. The MEMS microphone according to claim 3, wherein a cross-sectional area of the first connecting portion is larger than that of the second connecting portion.

5. The MEMS microphone according to claim 3, wherein a cross-section of the first connecting portion and a cross-section of the second connecting portion are both circular.

6. The MEMS microphone according to claim 4, wherein an air gap is formed between each of the plurality of isolation islands and the back plate.

7. The MEMS microphone according to claim 6, wherein a connecting surface is formed at a position where the first connecting portion is fixedly connected with the second connecting portion; and along a vibration direction of the diaphragm, the air gap includes a first gap formed between a surface, facing towards the corresponding one of the plurality of isolation islands, of the back plate and the connecting surface, and includes a second gap formed between a surface, facing towards the back plate, of the corresponding one of the plurality of isolation islands and the connecting surface.

8. The MEMS microphone according to claim 1, wherein the connecting piece is fixedly connected to the substrate; and the connecting piece is integrally formed with the substrate.

9. The MEMS microphone according to claim 8, wherein the connecting piece includes an anchor which is fixedly connected between the corresponding one of the plurality of isolation islands and the substrate.

10. The MEMS microphone according to claim 9, wherein a cross-section of the anchor along a direction perpendicular to a vibration direction of the diaphragm is a hollow rounded rectangle; and the anchor is filled with an oxide isolation layer.

11. The MEMS microphone according to claim 1, wherein along a vibration direction of the diaphragm, an orthographic projection of each of the plurality of isolation islands on the back plate covers that of the connecting piece on the back plate; and/or, an orthographic projection of each of the plurality of isolation islands on the substrate covers that of the connecting piece on the substrate.

12. The MEMS microphone according to claim 1, wherein along a vibration direction of the diaphragm, an orthographic projection of the connecting piece on the corresponding one of the plurality of isolation islands is located in the center of the corresponding one of the plurality of isolation islands.

13. The MEMS microphone according to claim 1, wherein the beam is located between two adjacent slits.
